(19) United States
(12) Patent Application Publication
(10) Pub. No.: US 2022/0216214 A1
(43) Pub. Date: Jul. 7, 2022

(54) SEMICONDUCTOR STRUCTURE MANUFACTURING METHOD AND SEMICONDUCTOR STRUCTURE

(71) Applicant: CHANGXIN MEMORY TECHNOLOGIES, INC., Hefei City (CN)

(72) Inventors: Xinman CAO, Hefei (CN); Zhongming LIU, Hefei (CN); JUN XIA, Hefei (CN); SHIJIE BAI, Hefei (CN)

(73) Assignee: CHANGXIN MEMORY TECHNOLOGIES, INC., Hefei City (CN)

(21) Appl. No.: 17/447,430

(22) Filed: Sep. 12, 2021

Related U.S. Application Data
(63) Continuation of application No. PCT/CN2021/103720, filed on Jun. 30, 2021.

(30) Foreign Application Priority Data
Jan. 4, 2021 (CN) 202110004433.4

(51) Int. Cl. H01L 27/108; H01L 21/3213

(52) U.S. Cl. CPC H01L 27/10855; H01L 21/32139; H01L 27/10808

(57) ABSTRACT

A semiconductor structure manufacturing method includes: forming a first pattern transfer layer on a conductive layer; forming a first mask layer having a plurality of first hole-shaped patterns disposed at intervals on the first pattern transfer layer, and etching the first pattern transfer layer by using the first mask layer as a mask to form first holes; and forming a second pattern transfer layer. The first holes are formed on the first pattern transfer layer. While forming the second pattern transfer layer by spin-on hardmask, there is a smaller amount of the second pattern transfer layer filling the first holes and a larger amount of the second pattern transfer layer located on the first pattern transfer layer.

### CROSS-REFERENCE TO RELATED APPLICATIONS

This application is a continuation of International Patent Application No. PCT/CN2021/103720 filed on Jun. 30, 2021, which claims priority to Chinese Patent Application No. 202110004433.4 filed on Jan. 4, 2021. the disclosures of these applications are hereby incorporated by reference in their entirety.

### BACKGROUND

With the gradual development of storage device technology, a Dynamic Random-Access Memory (DRAM) is gradually used in various electronic devices with its higher density and higher reading and writing speed. The dynamic random-access memory includes a storage unit. The storage unit includes a transistor structure and a capacitor structure electrically connected to the transistor structure. By using the transistor structure, reading data in the capacitor structure or writing data into the capacitor structure can be realized.

### SUMMARY

Embodiments of the present disclosure relate to the technical field of semiconductor manufacturing, and in particular to a semiconductor structure manufacturing method and a semiconductor structure.

An embodiment of the present disclosure provides a semiconductor structure manufacturing method, including: providing a substrate, the substrate including a core region and an edge region located on periphery of the core region, and a conductive layer being formed on the substrate; forming a first pattern transfer layer on the conductive layer; forming a first mask layer having a plurality of first hole-shaped patterns disposed at intervals on the first pattern transfer layer, and etching the first pattern transfer layer by using the first mask layer as a mask to form first holes; forming a first isolation layer, the first isolation layer at least covering side walls of the first holes; forming a second pattern transfer layer, the second pattern transfer layer filling the first holes and at least covering the first isolation layer; forming a second mask layer having a plurality of second hole-shaped patterns disposed at intervals on the second pattern transfer layer, a projection of each of the second hole-shaped patterns onto the substrate being located between projections of the adjacent first holes onto the substrate; etching the first pattern transfer layer by using the second mask layer as a mask to form second holes, an aperture size of the second hole being the same as an aperture size of the first hole; forming a second isolation layer, the second isolation layer at least covering side walls of the second holes; and forming a third pattern transfer layer, the third pattern transfer layer filling the second holes.

An embodiment of the present disclosure further provides a semiconductor structure manufactured by the method described above, including a substrate and contact pad structures formed on the substrate. One end of the contact pad structure is connected to a transistor structure in the substrate, and the other end of the contact pad structure is configured to be connected to the capacitor structure.

### BRIEF DESCRIPTION OF THE DRAWINGS

In order to more clearly illustrate the embodiments of the present disclosure or the technical solutions in the prior art, the drawings required to be used in the description of the embodiments or the prior art will be briefly described below. It is apparent that the drawings in the following description are only some embodiments of the present disclosure, and those skilled in the art can obtain other drawings according to these drawings without any creative work.

FIG. 1 is a flow chart of a semiconductor structure manufacturing method provided by an embodiment of the present disclosure.

FIG. 2 is a top view after a first mask layer is formed in the semiconductor structure manufacturing method provided by the embodiment of the present disclosure.

FIG. 3 is a sectional view of a core region after the first mask layer is formed in the semiconductor structure manufacturing method provided by the embodiment of the present disclosure.

FIG. 4 is a top view of FIG. 2.

FIG. 5 is a sectional view of an edge region after the first mask layer is formed in the semiconductor structure manufacturing method provided by the embodiment of the present disclosure.

FIG. 6 is a top view of FIG. 5.

FIG. 7 is a sectional view of the core region after the first holes are formed on the first pattern transfer layer in the semiconductor structure manufacturing method provided by the embodiment of the present disclosure.

FIG. 8 is a top view of FIG. 7.

FIG. 9 is a sectional view of the edge region after the first holes are formed on the first pattern transfer layer in the semiconductor structure manufacturing method provided by the embodiment of the present disclosure.

FIG. 10 is a top view of FIG. 9.

FIG. 11 is a sectional view of the core region after the first isolation layer is formed in the semiconductor structure manufacturing method provided by the embodiment of the present disclosure.

FIG. 12 is a top view of FIG. 11.

FIG. 13 is a sectional view of the edge region after the first isolation layer is formed in the semiconductor structure manufacturing method provided by the embodiment of the present disclosure.

FIG. 14 is a top view of FIG. 13.

FIG. 15 is a sectional view of the core region after a part of the first isolation layer is removed in the semiconductor structure manufacturing method provided by the embodiment of the present disclosure.

FIG. 16 is a top view of FIG. 15.

FIG. 17 is a sectional view of the edge region after the part of the first isolation layer is removed in the semiconductor structure manufacturing method provided by the embodiment of the present disclosure.

FIG. 18 is a top view of FIG. 17.

FIG. 19 is a schematic diagram after a second pattern transfer layer is formed in the semiconductor structure manufacturing method provided by the embodiment of the present disclosure.

FIG. 20 is a sectional view of the core region after the second pattern transfer layer is formed in the semiconductor structure manufacturing method provided by the embodiment of the present disclosure.

FIG. 21 is a top view of FIG. 20.

FIG. 22 is a sectional view of the edge region after the second pattern transfer layer is formed in the semiconductor structure manufacturing method provided by the embodiment of the present disclosure.

FIG. 23 is a top view of FIG. 22.

FIG. 24 is a top view after a second mask layer is formed in the semiconductor structure manufacturing method provided by the embodiment of the present disclosure.

FIG. 25 is a sectional view of the core region after the second mask layer is formed in the semiconductor structure manufacturing method provided by the embodiment of the present disclosure.

FIG. 26 is a top view of FIG. 25.

FIG. 27 is a sectional view of the edge region after the second mask layer is formed in the semiconductor structure manufacturing method provided by the embodiment of the present disclosure.

FIG. 28 is a top view of FIG. 27.

FIG. 29 is a sectional view of the core region after the second holes are formed in the semiconductor structure manufacturing method provided by the embodiment of the present disclosure.

FIG. 30 is a top view of FIG. 29.

FIG. 31 is a sectional view of the edge region after the second holes are formed in the semiconductor structure manufacturing method provided by the embodiment of the present disclosure.

FIG. 32 is a top view of FIG. 31.

FIG. 33 is a sectional view of the core region after the second isolation layer is formed in the semiconductor structure manufacturing method provided by the embodiment of the present disclosure.

FIG. 34 is a top view of FIG. 33.

FIG. 35 is a sectional view of the edge region after the second isolation layer is formed in the semiconductor structure manufacturing method provided by the embodiment of the present disclosure.

FIG. 36 is a top view of FIG. 35.

FIG. 37 is a sectional view of the core region after the third pattern transfer layer is formed in the semiconductor structure manufacturing method provided by the embodiment of the present disclosure.

FIG. 38 is a top view of FIG. 37.

FIG. 39 is a sectional view of the edge region after the third pattern transfer layer is formed in the semiconductor structure manufacturing method provided by the embodiment of the present disclosure.

FIG. 40 is a top view of FIG. 39.

FIG. 41 is a sectional view of the core region after the second isolation layer located on an upper surface of the second pattern transfer layer is removed in the semiconductor structure manufacturing method provided by the embodiment of the present disclosure.

FIG. 42 is a top view of FIG. 41.

FIG. 43 is a sectional view of the edge region after the second isolation layer located on the upper surface of the second pattern transfer layer is removed in the semiconductor structure manufacturing method provided by the embodiment of the present disclosure.

FIG. 44 is a top view of FIG. 43.

FIG. 45 is a sectional view of the core region after pad structures are formed in the semiconductor structure manufacturing method provided by the embodiment of the present disclosure.

FIG. 46 is a top view of FIG. 45.

FIG. 47 is a sectional view of the edge region after the pad structures are formed in the semiconductor structure manufacturing method provided by the embodiment of the present disclosure; and

FIG. 48 is a top view of FIG. 47.

### SPECIFICATION OF THE REFERENCE SIGNS

1: core region; 2: edge region;

10: substrate; 101: conductive layer;

102: contact pad structure; 20: hardmask;

30: first pattern transfer layer; 301: first hole;

302: first trench; 303: second hole;

304: third hole; 40: first mask layer;

401: first hole-shaped pattern; 402: first trench-shaped pattern;

50: final pattern transfer layer; 60: first isolation layer;

70: second mask layer; 701: second hole-shaped pattern;

702: third hole-shaped pattern; 80: second pattern transfer layer;

801: second isolation layer; 90: third pattern transfer layer.

### DETAILED DESCRIPTION

In order to make the objects, technical solutions and advantages of the embodiments of the present disclosure clearer, the technical solutions in the embodiments of the present disclosure will be clearly and completely described below in combination with the accompanying drawings in the embodiments of the present disclosure. It is apparent that the described embodiments are a part of the embodiments of the present disclosure, rather than all of the embodiments. All other embodiments obtained by those of ordinary skill in the art based on the embodiments of the present disclosure without creative work are within the protection scope of the present disclosure.

Typically, a transistor structure is disposed in a substrate, and the transistor structure is connected to the capacitor structure through a contact pad structure disposed on the substrate. During the manufacturing of the contact pad structure, a conductive layer is formed on the substrate, and then a first pattern transfer layer and a first mask layer are sequentially formed. The first mask layer is provided with a first trench-shaped pattern extending along a first direction, and the first pattern transfer layer is etched by using the first mask layer as a mask so as to form a first trench on the first pattern transfer layer. Then, a second pattern transfer layer and a second mask layer are formed on the first pattern transfer layer. The second mask layer is provided with a second trench-shaped pattern extending along a second direction. There is a certain included angle between the first direction and the second direction. The first pattern transfer layer is etched by using the second mask layer as a mask so as to form a second trench on the first pattern transfer layer. The first trenches and the second trenches form an etching region. The conductive layer corresponding to the etching region is removed, so that the contact pad structures are formed on the conductive layer.

However, after the first pattern transfer layer is etched through the first mask layer, the second pattern transfer layer needs to be formed by spin-on hardmask (SOH). During the spin-on hardmask, the first trenches are filled with the liquid second pattern transfer layer. Since a volume of the first trench is larger, a thickness of the second pattern transfer layer covering the first pattern transfer layer is smaller. As a result, there is a big thickness difference between the second pattern transfer layer corresponding to an edge region of the substrate and the second pattern transfer layer corresponding to a core region, which will affect the subsequent process.

A dynamic random-access memory includes a storage unit. The storage unit includes a transistor structure and a capacitor structure electrically connected to the transistor structure. By using the transistor structure, reading data in the capacitor structure or writing data into the capacitor structure can be realized.

The transistor structures are disposed in a substrate, and a transistor structure is connected to the capacitor structure through a contact pad structure disposed on the substrate. During the manufacturing of the contact pad structures, a conductive layer is formed on the substrate, and then a first pattern transfer layer and a first mask layer are sequentially formed. The first mask layer is provided with a first trench-shaped pattern extending along a first direction, and the first pattern transfer layer is etched by using the first mask layer as a mask so as to form a first trench on the first pattern transfer layer. Then, a second pattern transfer layer and a second mask layer are formed on the first pattern transfer layer. The second mask layer is provided with a second trench-shaped pattern extending along a second direction. There is a certain included angle between the first direction and the second direction. The first pattern transfer layer is etched by using the second mask layer as a mask so as to form a second trench on the first pattern transfer layer. The first trenches and the second trenches form an etching region. The conductive layer corresponding to the etching region is removed, so that the contact pad structures are formed on the conductive layer.

However, after the first pattern transfer layer is etched through the first mask layer, the second pattern transfer layer needs to be formed by spin-on hardmask (SOH). During the spin-on hardmask, the first trenches are filled with the liquid second pattern transfer layer. Since a volume of the first trench is larger, a thickness of the second pattern transfer layer covering the first pattern transfer layer is smaller, as a result, there is a big thickness difference between the second pattern transfer layer corresponding to an edge region of the substrate and the second pattern transfer layer corresponding to a core region, which will affect the subsequent process.

An embodiment of the present disclosure provides a semiconductor structure manufacturing method. A first pattern transfer layer and a first mask layer are sequentially formed on a conductive layer, and the first mask layer is provided first holes-shaped pattern. The first pattern transfer layer is etched by using the first mask layer as a mask to form first holes. When a second pattern transfer layer is formed on the first mask layer by spin-on hardmask, a volume of the first hole is smaller, and there is a smaller amount of material contained in the first hole and a larger amount of material covering the first mask layer, so that the thickness difference of the material corresponding to the core region and the edge region can be reduced, thereby avoiding affecting the subsequent process.

The semiconductor structure in this embodiment may be a Dynamic Random-Access Memory (DRAM). The following description will take the semiconductor structure as a dynamic random-access memory as an example. Of course, this embodiment is not limited to this, and the semiconductor structure in this embodiment may also be other structures.

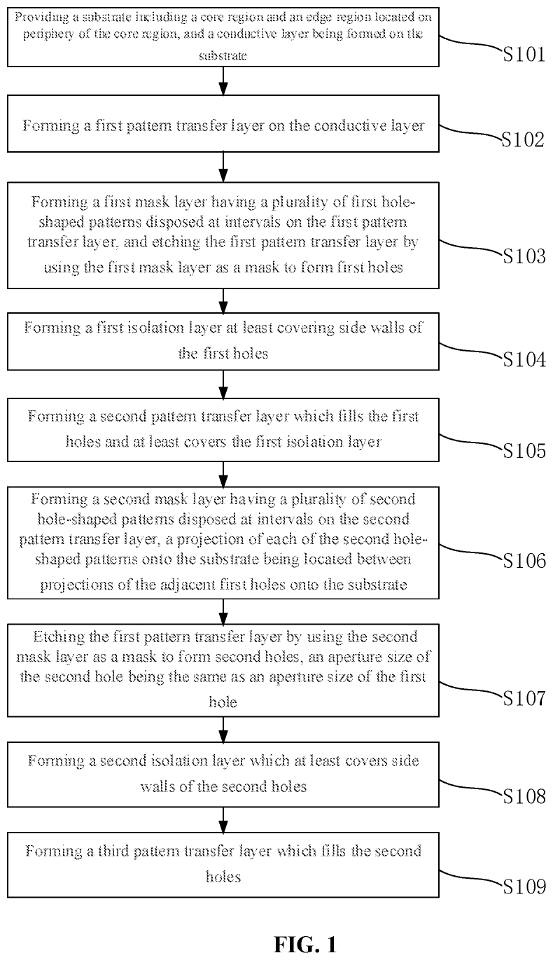

As illustrated in FIG. 1, the semiconductor structure manufacturing method provided by this embodiment includes steps as follows.

In S101, a substrate is provided. The substrate includes a core region and an edge region located on periphery of the core region, and a conductive layer is formed on the substrate.

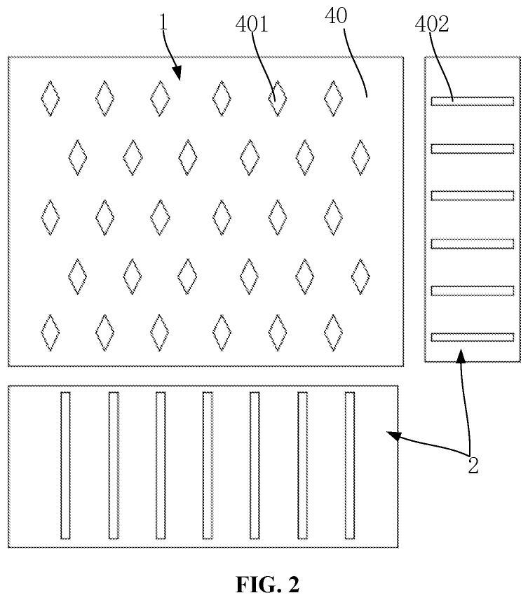

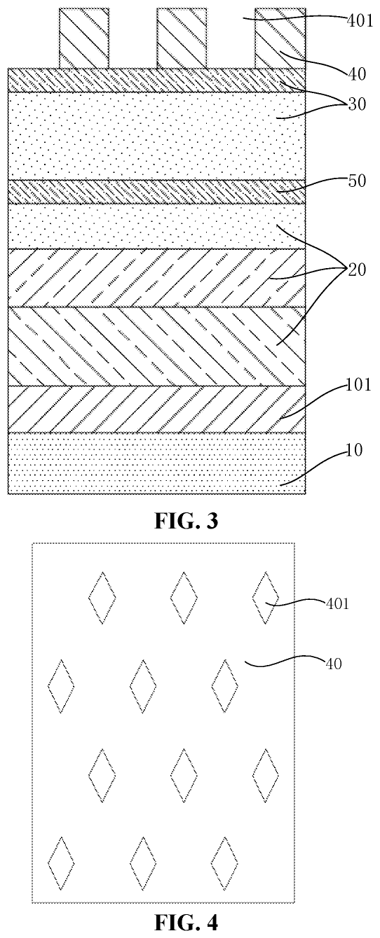

With reference to FIG. 2 to FIG. 4, the edge region 2 is located at the periphery of the core region 1. The edge may be connected to the core region 1. Of course, there may also be a certain distance between the edge region 2 and the core region 1. Further, the edge region 2 may be disposed around the core region 1. Of course, the edge region 2 may also be located on one side of the core region 1. In this embodiment, a material of the conductive layer 101 may include tungsten and the like. After forming the conductive layer 101, the conductive layer 101 covers the entire substrate 10, that is, the conductive layer 101 covers the edge region 2 and the core region 1.

In this embodiment, after forming the conductive layer 101, the method further includes a step as follows.

In S102, a first pattern transfer layer is formed on the conductive layer.

Continuing to refer to FIG. 2 to FIG. 4, exemplarily, a material of the first pattern transfer layer 30 may include carbon.

In this embodiment, before forming the first pattern transfer layer 30, the method further includes: forming a hardmask 20 on the conductive layer 101. The hardmask 20 may be a single-layer structure or a multilayer structure. In an implementation in which the hardmask 20 is a multilayer structure, the hardmask 20 may include an amorphous carbon layer, an oxide layer and a carbon layer that are sequentially stacked on the conductive layer 101.

In this embodiment, before forming the first pattern transfer layer 30, the method further includes: forming a final pattern transfer layer 50 on the conductive layer 101. The final pattern transfer layer 50 can serve as an etching stop layer in the subsequent etching step, and can also protect the conductive layer 101. Exemplarily, a material of the final pattern transfer layer 50 may include silicon oxynitride and the like.

In this embodiment, after forming the first pattern transfer layer 30, the method further includes a step as follows.

In S103, a first mask layer having a plurality of first hole-shaped patterns disposed at intervals is formed on the first pattern transfer layer, and the first pattern transfer layer is etched by using the first mask layer as a mask to form the first holes.

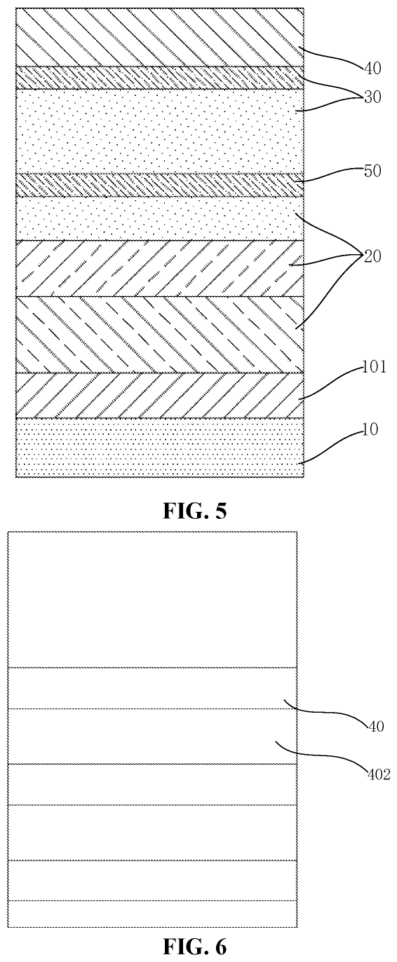

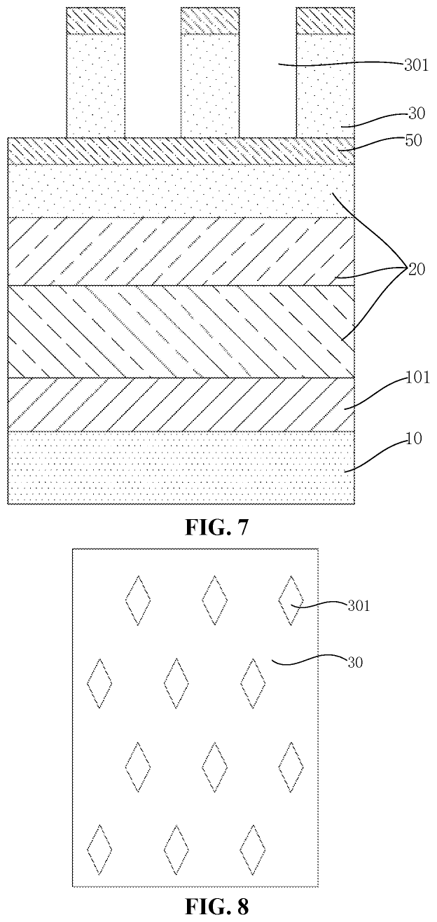

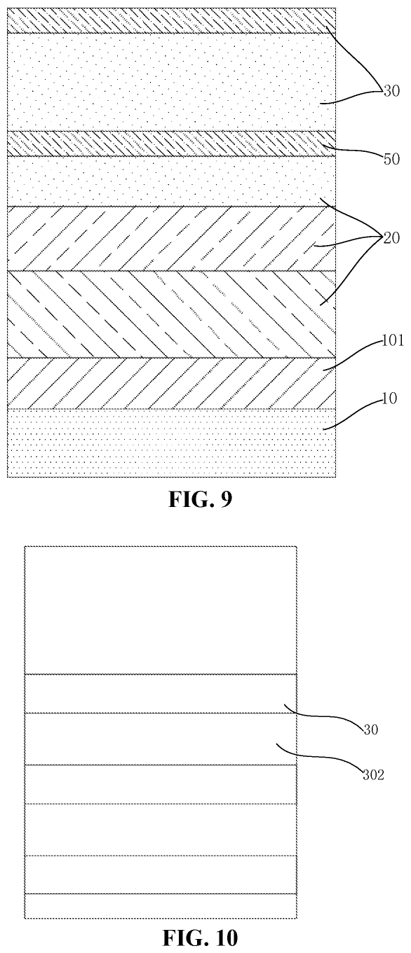

With reference to FIG. 2 to FIG. 10, in some implementations, a region corresponding to the core region 1 in the first mask layer 40 is provided with the first hole-shaped pattern 401, a region corresponding to the edge region 2 in the first mask layer 40 is further provided with a plurality of first trench-shaped patterns 402, the first trench-shaped pattern 402 extends along a direction away from the core region 1, and the plurality of first trench-shaped patterns 402 are disposed in parallel and at intervals. While etching the first pattern transfer layer 30 by using the first mask layer 40 as a mask, a first trench 302 is formed in a region corresponding to the edge region 2 in the first pattern transfer layer 30.

In the implementation above, the first pattern transfer layer 30 may be etched by dry etching or wet etching, but this embodiment is not limited to this.

In this embodiment, after forming first holes 301, the method includes a step as follows.

In S104, a first isolation layer is formed. The first isolation layer at least covers side walls of the first holes.

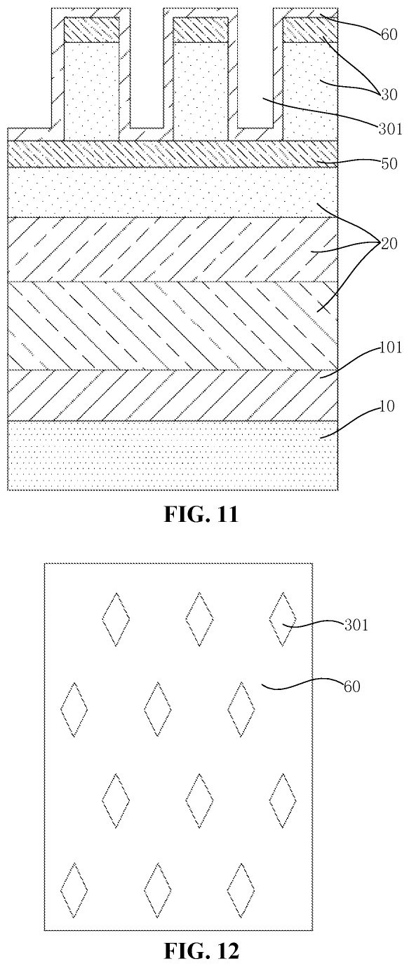

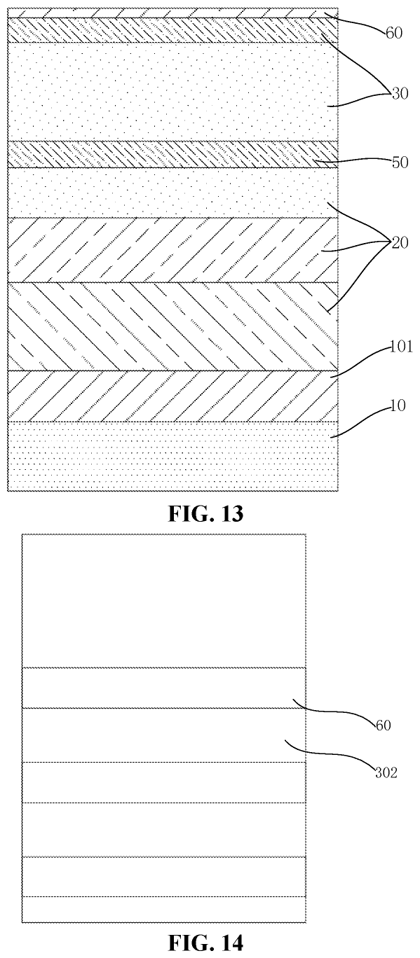

With reference to FIG. 11 to FIG. 14, exemplarily, a material of a first isolation layer 60 may include silicon oxide and other oxides. The first isolation layer 60 may cover bottom walls and the side walls of the first holes 301 and an upper surface of the first pattern transfer layer 30.

In an implementation in which the first trenches 302 are formed in the first pattern transfer layer 30 corresponding to the edge region 2, while forming the first isolation layer 60, the first isolation layer 60 further at least covers side walls of the first trenches 302. Exemplarily, the first isolation layer 60 may cover bottom walls and side walls of the first trenches 302 and the upper surface of the first pattern transfer layer 30 corresponding to the edge region 2.

In this embodiment, after forming the first isolation layer 60, the method further includes a step as follows.

In S105, a second pattern transfer layer is formed. The second pattern transfer layer fills the first holes and at least covers the first isolation layer.

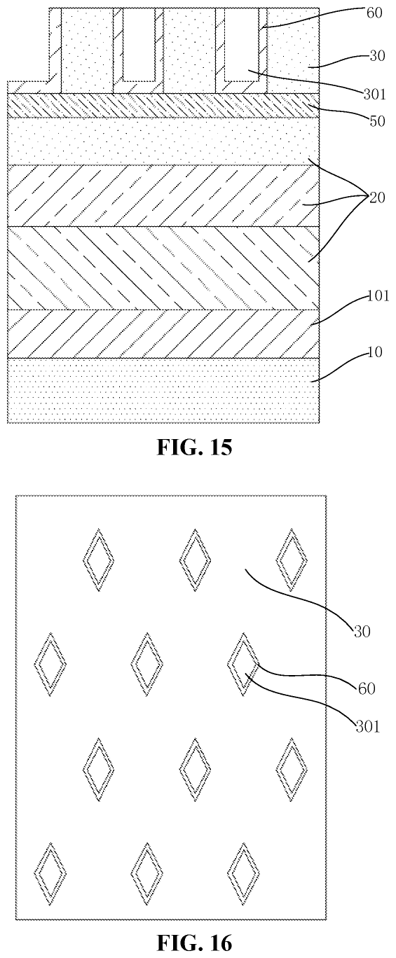

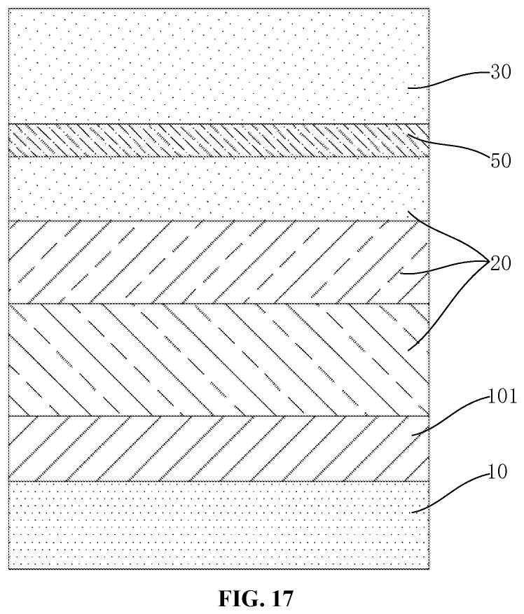

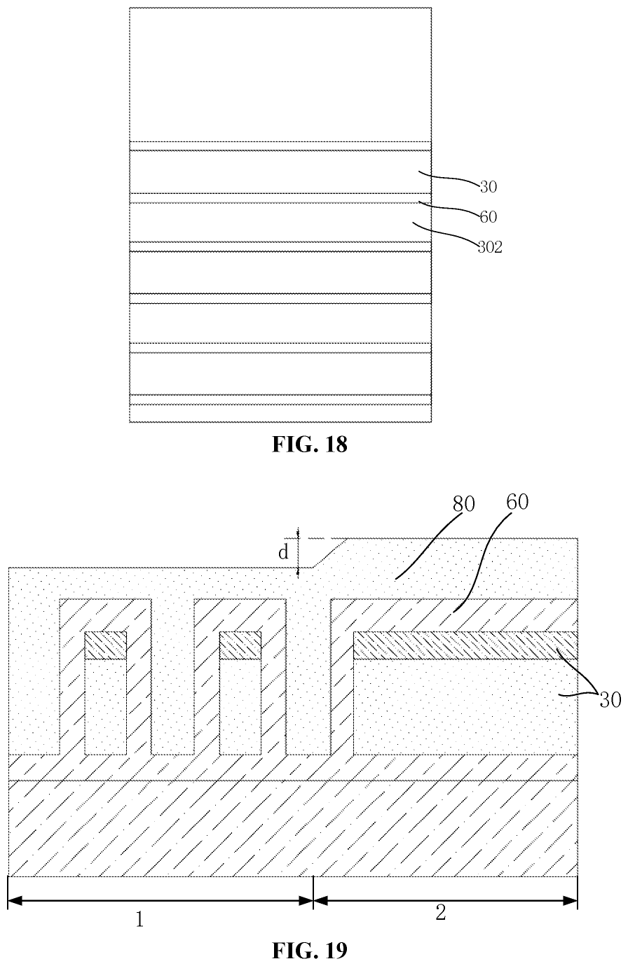

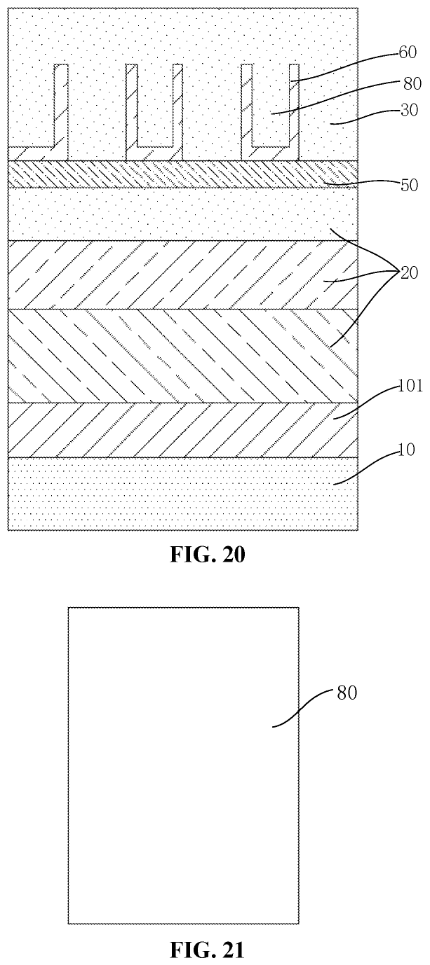

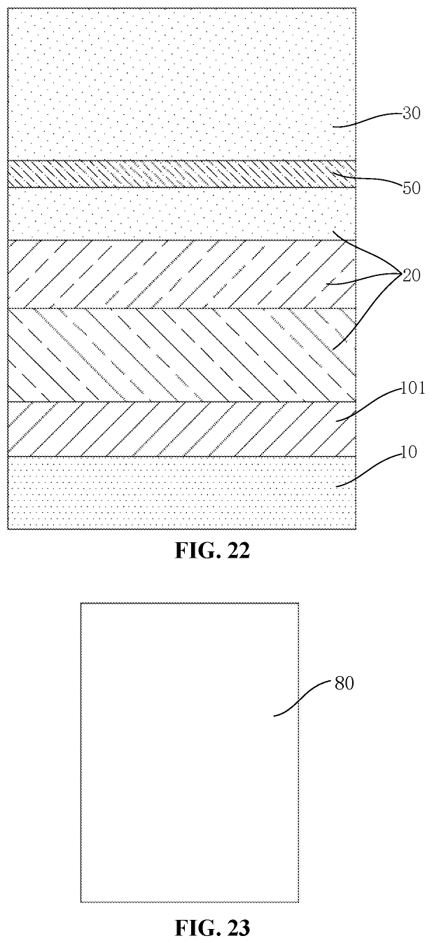

With reference to FIG. 15 to FIG. 23, exemplarily, a material of the second pattern transfer layer 80 may include carbon.

The second pattern transfer layer 80 may be formed by spin-on hardmask. Since a pattern disposed in the core region 1 of the first pattern transfer layer 30 is the first holes 301, the volume of the first holes 301 is smaller. While forming the second pattern transfer layer 80, there is a larger amount of the second pattern transfer layer 80 located on the first pattern transfer layer 30. Therefore, the thickness difference of the second pattern transfer layer 80 corresponding to the core region and the edge region 2 (the thickness difference d illustrated in FIG. 19) can be reduced, thereby avoiding affecting the subsequent process.

In an implementation in which the first trenches 302 are formed in the first pattern transfer layer 30 corresponding to the edge region 2, while forming the second pattern transfer layer 80, the second pattern transfer layer 80 further fills the first trenches 302. Further, a width size of the second pattern transfer layer 80 filling the first trenches 302 is the same as a width size of the remaining first pattern transfer layer 30 located in the corresponding edge region 2 after forming the first trenches 302. With this disposition, the dimensional accuracy of the second pattern transfer layer 80 can be improved.

In a possible implementation, the first isolation layer 60 covers the upper surface of the first pattern transfer layer 30, the side walls and bottom walls of the first holes 301 and the side wall and a bottom wall of the first trenches 302. Before forming the second pattern transfer layer 80, the method further includes: removing a part of the first isolation layer 60 located on the upper surface of the first pattern transfer layer 30, on the bottom walls of the first holes 301 and on the bottom walls of the first trenches 302 to reserve a part of the first isolation layer 60 located on the side walls of the first holes 301 and on the side walls of the first trenches 302.

Exemplarily, the part of the first isolation layer 60 may be removed by dry etching or wet etching. Further, while removing the part of the first isolation layer 60, the first pattern transfer layer 30 near the upper surface may be removed.

In other implementations, the first isolation layer 60 covers the upper surface of the first pattern transfer layer 30, the side walls and the bottom walls of the first holes 301 and the side walls and the bottom walls of the first trenches 302. Before forming the second pattern transfer layer 80, a part of the first isolation layer 60 located on the upper surface of the first pattern transfer layer 30 is removed to reserve the first isolation layer 60 located on the side walls and the bottom walls of the first holes 301 and on the side walls and the bottom walls of the first trenches 302 (as illustrated in FIG. 15 to FIG. 18).

In this embodiment, after forming the second pattern transfer layer 80, the method further includes a step as follows.

In S106, a second mask layer having a plurality of second hole-shaped patterns disposed at intervals is formed on the second pattern transfer layer. A projection of each of the second hole-shaped patterns onto the substrate is located between projections of the adjacent first holes onto the substrate.

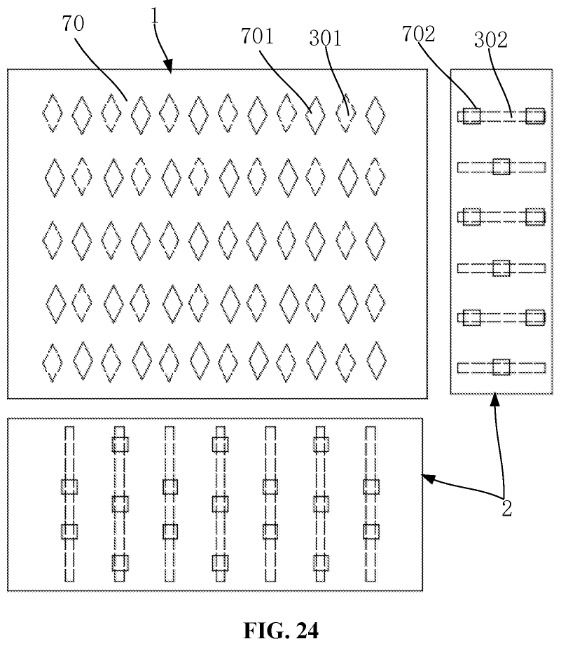

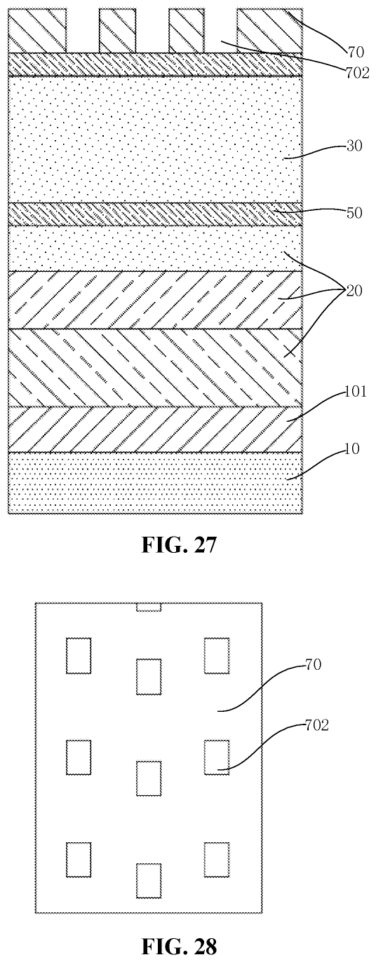

As illustrated in FIG. 24 to FIG. 28, exemplarily, the second hole-shaped pattern 701 may be formed on the second mask layer 70 by etching.

After forming the second hole-shaped pattern 701, the method includes a step as follows:

In S107, the first pattern transfer layer is etched by using the second mask layer as a mask to form second holes. An aperture size of the second hole is the same as an aperture size of the first hole.

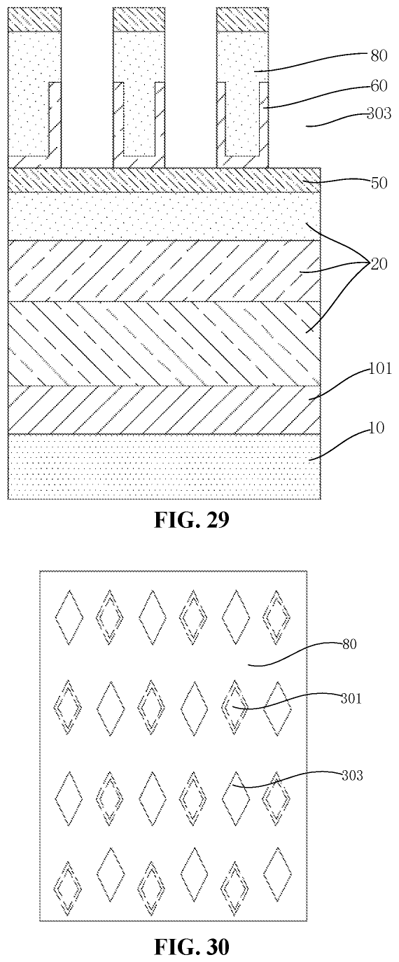

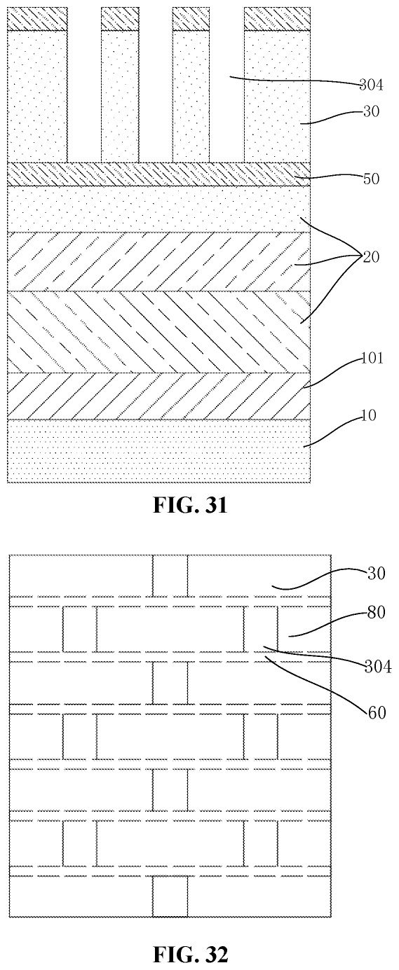

Continuing to refer to FIG. 29 to FIG. 32, since the projection of the second hole-shaped pattern 701 on the substrate 10 is located between the projections of the adjacent first holes 301 on the substrate 10, the formed second holes 303 are also located between the adjacent first holes 301. Exemplarily, the projections of the first holes 301 and the second holes 303 on the substrate 10 are disposed in arrays, and a row of the second holes 303 is disposed between any two adjacent rows of the first holes 301. Or one column of the second holes 303 is disposed between every two adjacent columns of the first holes 301.

The first holes 301 and the second holes 303 have the same aperture size, so that the dimensional accuracy of the formed contact pad structures can be improved, thereby improving performance of the manufactured semiconductor device.

Further, after forming the second holes 303, the semiconductor structure manufacturing method provided by this embodiment further includes a step as follows.

In S108, a second isolation layer is formed. The second isolation layer at least covers side walls of the second holes.

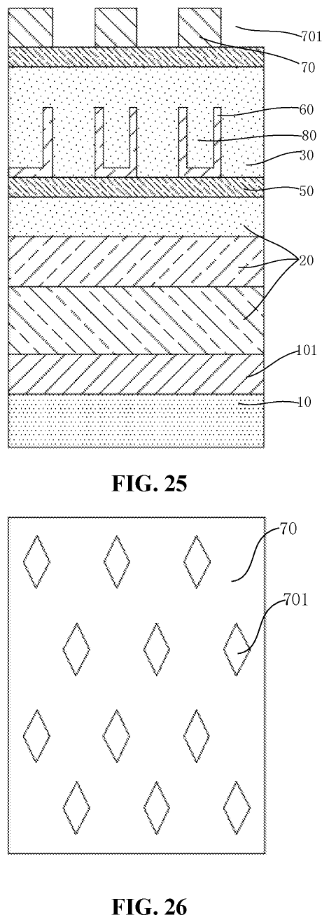

Continuing to refer to FIG. 25 to FIG. 28, in some implementations, a region corresponding to the core region 1 in the second mask layer 70 is provided with the second hole-shaped pattern 701, a region corresponding to the edge region 2 in the second mask layer 70 is provided with a plurality of third hole-shaped patterns 702, and a projection of the third hole-shaped pattern 702 on the first pattern transfer layer 30 or the second pattern transfer layer 80 is located between the adjacent first isolation layers 60 covering the side walls of the first trenches 302.

As illustrated in FIG. 29 to FIG. 32, while etching the first pattern transfer layer 30 by using the second mask layer 70 as a mask to form the second holes 303, regions respectively corresponding to the edge region 2 in the first pattern transfer layer 30 and the second pattern transfer layer 80 are etched to form third holes 304 corresponding to the third hole-shaped pattern 702, and side wall of the third holes 304 are in contact with the adjacent first isolation layers 60. While forming the second isolation layer 801, the second isolation layer 801 further at least fills the third holes 304.

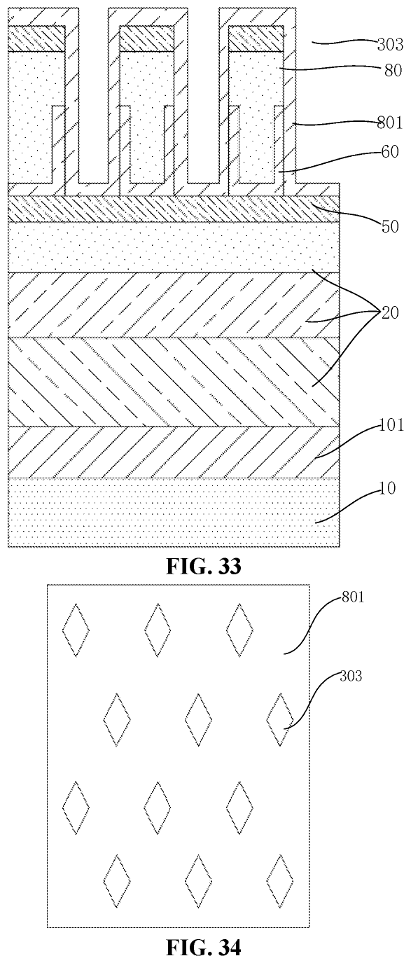

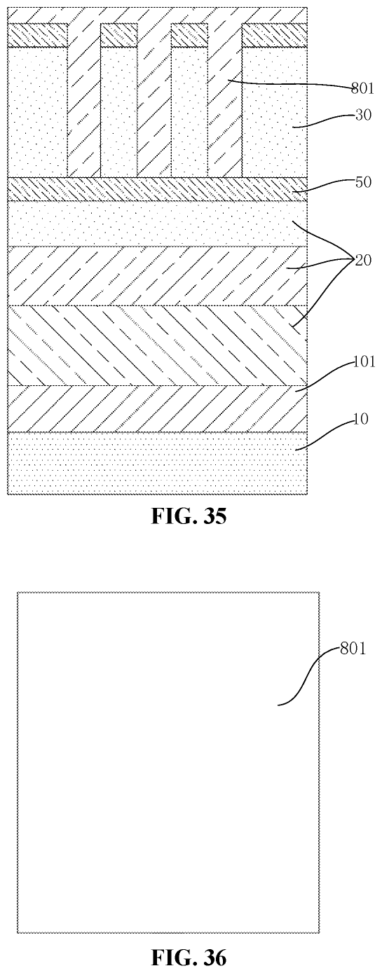

As illustrated in FIG. 33 to FIG. 36, through the first isolation layer 60 and the second isolation layer 801 in the core region 1, the contact pad structures connected to the capacitor structures may be formed on the conductive layer in the core region 1. Through the first isolation layer 60 and the second isolation layer 801 in the edge region 2, the contact pad structures having a certain pattern may be formed on the conductive layer 101 in the edge region 2.

After forming the second isolation layer 801, the semiconductor structure manufacturing method provided by this embodiment further includes a step as follows.

In S109, a third pattern transfer layer is formed. The third pattern transfer layer fills the second holes.

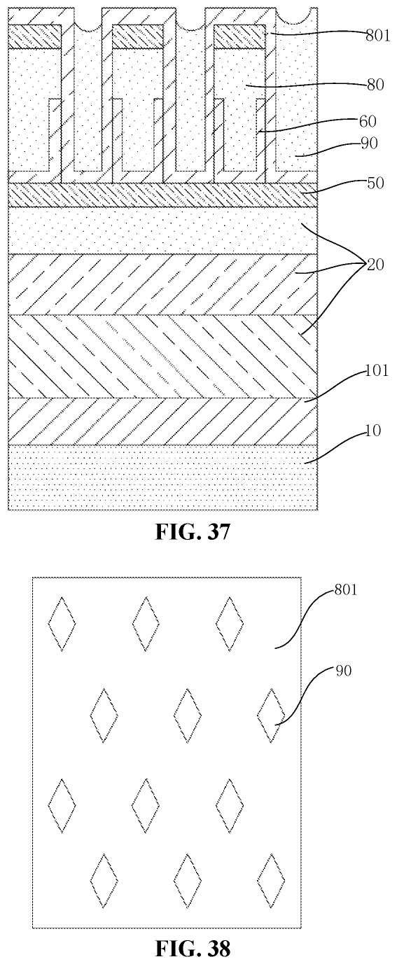

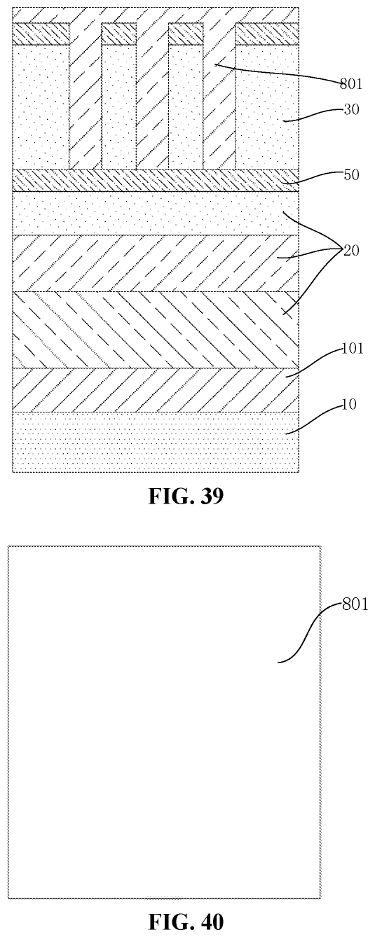

As illustrated in FIG. 37 to FIG. 40, the third pattern transfer layer 90 may support the second isolation layer 801 in the second holes 303, thereby preventing the second isolation layer 801 in the second holes 303 from coming off.

Further, the formation the second isolation layer 801 further includes: the second isolation layer 801 further covers the upper surface of the first pattern transfer layer 30 or the second pattern transfer layer 80 and the side walls and bottom walls of the second holes 303, and the second isolation layer 801 fully fills the third holes 304.

Before forming the third pattern transfer layer 90, the method further includes a step as follows.

A part of the second isolation layer 801 located on the upper surface of the first pattern transfer layer 30 or the second pattern transfer layer 80 and on the bottom walls of the second holes 303 is removed to reserve a part of the second isolation layer 801 located on the side wall of the second holes 303 and in the third holes 304.

In the implementation above, the formation of the third pattern transfer layer 90 further includes steps as follows.

The third pattern transfer layer 90 fully fills the second holes 303 and further covers the upper surface of the first pattern transfer layer 30, the upper surface of the second pattern transfer layer 80, an upper surface of the first isolation layer 60 and an upper surface of the second isolation layer 801. A part of the third pattern transfer layer 90 located on the upper surface of the first pattern transfer layer 30, on the upper surface of the second pattern transfer layer 80, on the upper surface of the first isolation layer 60 and on the upper surface of the second isolation layer 801 is removed to at least expose the upper surface of the first isolation layer 60 and the upper surface of the second isolation layer 801 and reserve a part of the third pattern transfer layer 90 located in the second holes 303.

Exemplarily, the part of the third pattern transfer layer 90 may be removed by etching, and the third pattern transfer layer 90 in the second holes 303 is reserved.

In this embodiment, the third pattern transfer layer 90 may be formed by spin-on hardmask, which simplifies the manufacturing difficulty. In addition, the plurality of second holes 303 are formed on the first pattern transfer layer 30, and the volume of the second hole 303 is smaller. While forming the third pattern transfer layer 90, the thickness of the first pattern transfer layer 30 in the core region 1 and the third pattern transfer layer 90 on the second pattern transfer layer 80 is larger, so the thickness difference of the third pattern transfer layer 90 in the core region 1 and the edge region 2 is reduced, thereby avoiding affecting the subsequent process.

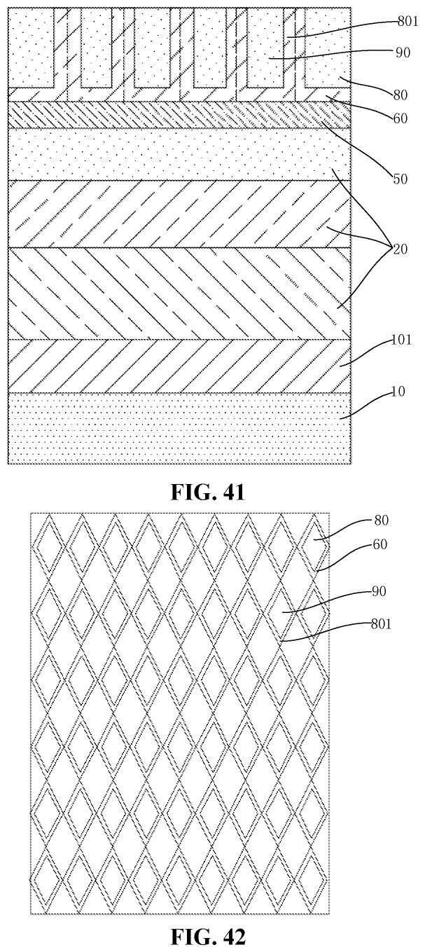

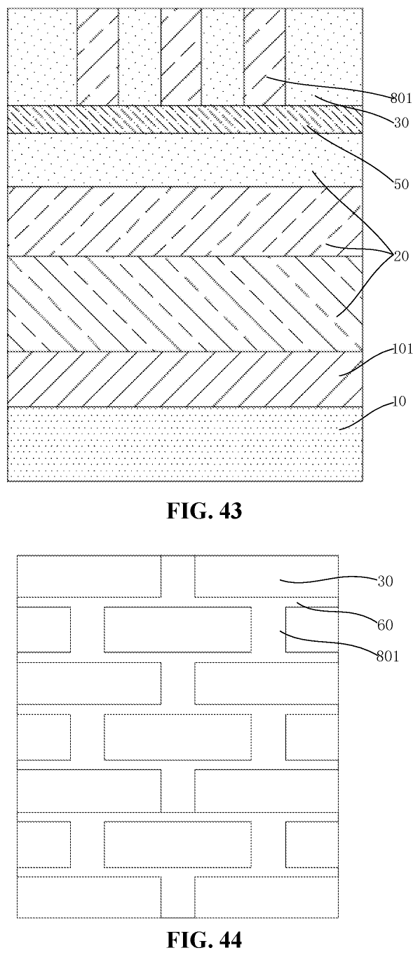

As illustrated in FIG. 41 to FIG. 44, further, after the part of the third pattern transfer layer 90 located on the upper surface of the first pattern transfer layer 30, on the upper surface of the second pattern transfer layer 80, on the upper surface of the first isolation layer 60 and on the upper surface of the second isolation layer 801 is removed, the method further includes: removing the second pattern transfer layer 80 and the second isolation layer 801 located on an upper part of the first isolation layer 60.

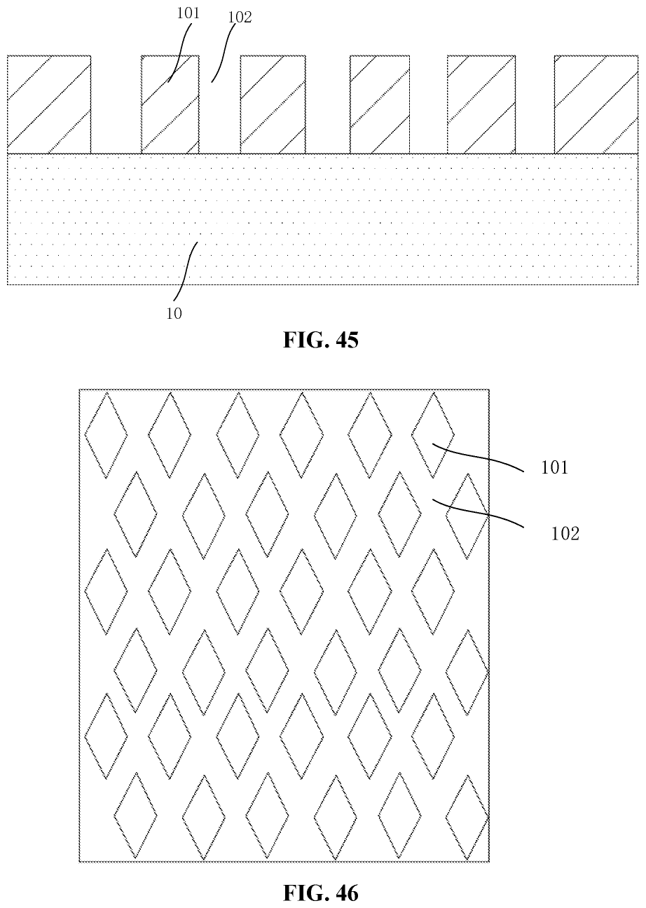

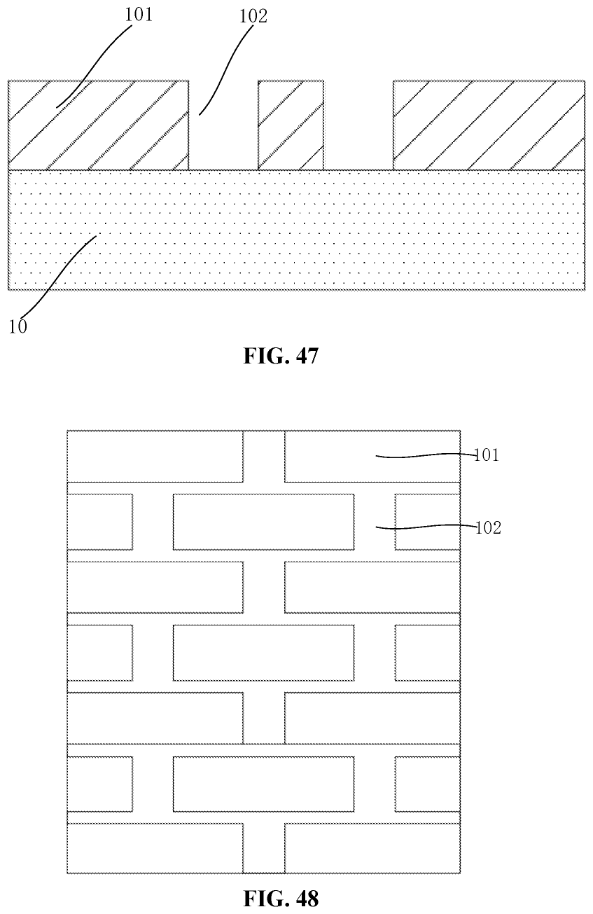

As illustrated in FIG. 45 to FIG. 48, after forming the third pattern transfer layer 90, the semiconductor structure manufacturing method provided by this embodiment further includes steps as follows.

The first isolation layer 60 and the second isolation layer 801 are removed by etching to form an isolation trench (not shown), and the conductive layer 101 is etched along the isolation trenches. The first pattern transfer layer 30, the second pattern transfer layer 80 and the third pattern transfer layer 90 on the conductive layer 101 are removed to form contact pad structures 102.

The isolation trenches located in the core region 1 form a plurality of reserved regions disposed in an array, and the isolation trenches located in the edge region 2 form a certain reserved pattern. After the conductive layer 101 is etched along the isolation trenches, the conductive layer 101 corresponding to the reserved regions and the reserved pattern is reserved, so that the contact pad structures 102 configured to be connected to the capacitor structures are formed in the core region 1. The contact pad structures 102 formed in the edge region 2 are a connecting line having a certain pattern.

With the disposition above, the dimensional accuracy of the formed contact pad structures 102 is improved, thereby improving performance of the semiconductor structure.

Further, the removing the first pattern transfer layer 30, the second pattern transfer layer 80 and the third pattern transfer layer 90 on the conductive layer 101 includes: etching the final pattern transfer layer 50 along the isolation trenches by self-aligned etching, and at the same time, removing the first pattern transfer layer 30, the second pattern transfer layer 80 and the third pattern transfer layer 90. With such disposition, the manufacturing steps of the semiconductor structure are simplified, and the manufacturing speed is improved.

In the implementation above, the etching the conductive layer 101 along the isolation trenches includes: etching the conductive layer 101 by using the etched final pattern transfer layer 50 as a mask. First, a pattern is transferred onto the final pattern transfer layer 50, and then, the conductive layer 101 is etched by using the final pattern transfer layer 50 as a mask, thereby improving the dimensional accuracy of the formed contact pad structures 102.

According to the semiconductor structure manufacturing method provided by this embodiment, the substrate 10 includes the core region 1 and the edge region 2 located at the periphery of the core region 1, and the substrate 10 is provided with the conductive layer 101. The first pattern transfer layer 30 is formed on the conductive layer 101. The first mask layer 40 having the plurality of first hole-shaped patterns 401 disposed at intervals is formed on the first pattern transfer layer 30, and the first pattern transfer layer 30 is etched by using the first mask layer 40 as a mask to form the first holes 301. Then, the first isolation layer 60 is formed, the first isolation layer 60 at least covering the side walls of the first holes 301. Then, the second pattern transfer layer 80 is formed, the second pattern transfer layer 80 filling the first holes 301 and at least covering the first isolation layer 60. The second mask layer 70 having the plurality of second hole-shaped patterns 701 disposed at intervals is formed on the second pattern transfer layer 80, the projection of each of the second hole-shaped patterns 701 on the substrate 10 being located between the projections of the first holes 301 on the substrate 10. The first pattern transfer layer 30 is etched by using the second mask layer 70 as a mask to form the second holes 303. Then, the second isolation layer 801 is formed, the second isolation layer 801 at least covering the side walls of the second holes 303. Then, the third pattern transfer layer 90 is formed, the third pattern transfer layer 90 filling the second holes 303. The first pattern transfer layer 30 is provided with the first holes 301. While forming the second pattern transfer layer 80 by spin-on hardmask, there is a smaller amount of the second pattern transfer layer 80 filling the first holes 301 and a larger amount of the second pattern transfer layer 80 located on the first pattern transfer layer 30, so the thickness difference of the second pattern transfer layer 80 in the core region 1 and the edge region 2 can be reduced, thereby avoiding affecting the subsequent process.

In addition, the second holes 303 are disposed on the first pattern transfer layer 30. While forming the third pattern transfer layer 90 by spin-on hardmask, there is a smaller amount of the third pattern transfer layer 90 filling the second holes 303 and thus a larger amount of the third pattern transfer layer 90 located on the second pattern transfer layer 80, so the thickness difference of the third pattern transfer layer 90 in the core region 1 and the edge region 2 can be reduced, thereby avoiding affecting the subsequent process.

Continuing to refer to FIG. 1 to FIG. 48, this embodiment further provides a semiconductor structure manufactured and formed by the semiconductor structure manufacturing method provided by any of the embodiments above, including a substrate 10 and contact pad structures 102 formed on the substrate 10. One end of the contact pad structure 102 is connected to a transistor structure in the substrate 10, and the other end of the contact pad structure 102 is configured to be connected to the capacitor structure.

The semiconductor structure in this embodiment may be a Dynamic Random-Access Memory (DRAM). Of course, this embodiment is not limited to this, and the semiconductor structure in this embodiment may also be other structures.

According to the semiconductor structure provided by this embodiment, the substrate 10 includes a core region 1 and an edge region 2 located on periphery of the core region 1, and the substrate 10 is provided with a conductive layer 101. A first pattern transfer layer 30 is formed on the conductive layer 101. A first mask layer 40 having a plurality of first hole-shaped patterns 401 disposed at intervals is formed on the first pattern transfer layer 30, and the first pattern transfer layer 30 is etched by using the first mask layer 40 as a mask to form first holes 301. Then, a first isolation layer 60 is formed, the first isolation layer 60 at least covering side walls of the first holes 301. Then, a second pattern transfer layer 80 is formed, the second pattern transfer layer 80 filling the first holes 301 and at least covering the first isolation layer 60. A second mask layer 70 having a plurality of second hole-shaped patterns 701 disposed at intervals is formed on the second pattern transfer layer 80, a projection of each of the second hole-shaped patterns 701 on the substrate 10 being located between projections of the first holes 301 on the substrate 10. The first pattern transfer layer 30 is etched by using the second mask layer 70 as a mask to form second holes 303. Then, a second isolation layer 801 is formed, the second isolation layer 801 at least covering side walls of the second holes 303. Then, a third pattern transfer layer 90 is formed, the third pattern transfer layer 90 filling the second holes 303. The first pattern transfer layer 30 is provided with the first holes 301. While forming the second pattern transfer layer 80 by spin-on hardmask, there is a smaller amount of the second pattern transfer layer 80 filling the first holes 301 and a larger amount of the second pattern transfer layer 80 located on the first pattern transfer layer 30, so the thickness difference of the second pattern transfer layer 80 in the core region 1 and the edge region 2 can be reduced, thereby avoiding affecting the subsequent process.

According to the semiconductor structure manufacturing method and the semiconductor structure provided by the embodiments, the substrate includes the core region and the edge region located at the periphery of the core region, and the substrate is provided with the conductive layer. The first pattern transfer layer is formed on the conductive layer. The first mask layer having the plurality of first hole-shaped patterns disposed at intervals is formed on the first pattern transfer layer, and the first pattern transfer layer is etched by using the first mask layer as a mask to form the first holes. Then, the first isolation layer is formed, the first isolation layer at least covering the side walls of the first holes. Then, the second pattern transfer layer is formed, the second pattern transfer layer filling the first holes and at least covering the first isolation layer. The second mask layer having the plurality of second hole-shaped patterns disposed at intervals is formed on the second pattern transfer layer, the projection of each of the second hole-shaped patterns onto the substrate being located between the projections of the first holes on the substrate. The first pattern transfer layer is etched by using the second mask layer as a mask to form the second holes. Then, the second isolation layer is formed, the second isolation layer at least covering the side walls of the second holes. Then, the third pattern transfer layer is formed, the third pattern transfer layer filling the second holes. The first pattern transfer layer is provided with the first holes. While forming the second pattern transfer layer by spin-on hardmask, there is a smaller amount of the second pattern transfer layers filling in the first holes and a larger amount of the second pattern transfer layers located on the first pattern transfer layer, so a thickness difference of the second pattern transfer layer in the core region and the edge region can be reduced, thereby avoiding affecting formation of subsequent film layers.

Finally, it should be noted that the embodiments above are only used to illustrate, but not to limit the technical solutions of the present disclosure. Although the present disclosure has been described in detail with reference to the foregoing embodiments, those of ordinary skill in the art should understand that they can still modify the technical solutions described in the foregoing embodiments, or equivalently substitute part of or all of the technical features. These modifications or substitutions do not make the essence of the corresponding technical solutions deviate from the scope of the technical solutions of the embodiments of the present disclosure.

1. A semiconductor structure manufacturing method, comprising:
providing a substrate, the substrate comprising a core region and an edge region located on periphery of the core region, and a conductive layer being formed on the substrate;
forming a first pattern transfer layer on the conductive layer;
forming a first mask layer having a plurality of first hole-shaped patterns disposed at intervals on the first pattern transfer layer, and etching the first pattern transfer layer by using the first mask layer as a mask to form first holes;
forming a first isolation layer, the first isolation layer at least covering side walls of the first holes;
forming a second pattern transfer layer, the second pattern transfer layer filling the first holes and at least covering the first isolation layer;
forming a second mask layer having a plurality of second hole-shaped patterns disposed at intervals on the second pattern transfer layer, a projection of each of the second hole-shaped patterns onto the substrate being located between projections of the adjacent first holes onto the substrate;
etching the first pattern transfer layer by using the second mask layer as a mask to form second holes, an aperture size of the second hole being the same as an aperture size of the first hole;
forming a second isolation layer, the second isolation layer at least covering side walls of the second holes; and
forming a third pattern transfer layer, the third pattern transfer layer filling the second holes.

2. The semiconductor structure manufacturing method of claim 1, wherein after forming the third pattern transfer layer, the method further comprises:
removing the first isolation layer and the second isolation layer by etching to form isolation trenches, and etching the conductive layer along the isolation trenches; and
removing the first pattern transfer layer, the second pattern transfer layer and the third pattern transfer layer on the conductive layer to form contact pad structures.

3. The semiconductor structure manufacturing method of claim 1, wherein a region, which corresponds to the core region, of the first mask layer is provided with the first hole-shaped patterns, a region, which corresponds to the edge region, of the first mask layer is further provided with a plurality of first trench-shaped patterns, the first trench-shaped pattern extends along a direction away from the core region, and the plurality of first trench-shaped patterns are disposed in parallel and at intervals;
while etching the first pattern transfer layer by using the first mask layer as a mask, first trenches areformed in a region, which corresponds to the edge region, of the first pattern transfer layer;
while forming the first isolation layer, the first isolation layer further at least covers side walls of the first trenches; and
while forming the second pattern transfer layer, the second pattern transfer layer fills the first trenches.

4. The semiconductor structure manufacturing method of claim 3, wherein a width size of the second pattern transfer layer filling the first trenches is the same as a width size of the remaining first pattern transfer layer located in the corresponding edge region after forming the first trenches.

5. The semiconductor structure manufacturing method of claim 3, wherein a region, which corresponds to the core region, of the second mask layer is provided with the second hole-shaped patterns, a region, which corresponds to the edge region, of the second mask layer is provided with a plurality of third hole-shaped patterns, and a projection of the third hole-shaped pattern onto the first pattern transfer layer or the second pattern transfer layer is located between the adjacent first isolation layers covering the side walls of the first trenches; and
while etching the first pattern transfer layer by using the second mask layer as a mask to form the second holes, regions, that respectively correspond to the edge region, of the first pattern transfer layer and the second pattern transfer layer are etched to form third holes corresponding to the third hole-shaped patterns, and side walls of the third holes are in contact with the adjacent first isolation layers; and
while forming the second isolation layer, the second isolation layer further at least fills the third holes.

6. The semiconductor structure manufacturing method of claim 5, wherein the forming the second isolation layer further comprises:
the second isolation layer further covers an upper surface of the first pattern transfer layer or the second pattern transfer layer, and the side walls and bottom walls of the second holes, and the second isolation layer fully fills the third holes,
and wherein before forming the third pattern transfer layer, the method further comprises:
removing a part of the second isolation layer located on the upper surface of the first pattern transfer layer or the second pattern transfer layer, and on the bottom walls of the second holes to reserve a part of the second isolation layer located on the side walls of the second holes and in the third holes.

7. The semiconductor structure manufacturing method of claim 3, wherein the forming the first isolation layer further comprises:
the first isolation layer covers an upper surface of the first pattern transfer layer, the side walls and bottom walls of the first holes and the side walls and bottom walls of the first trenches,
and wherein before forming the second pattern transfer layer, the method further comprises:
removing a part of the first isolation layer located on the upper surface of the first pattern transfer layer, on the bottom walls of the first holes and on the bottom walls of the first trenches to reserve a part of the first isolation layer located on the side walls of the first holes and on the side walls of the first trenches.

8. The semiconductor structure manufacturing method of claim 3, wherein forming the second pattern transfer layer further comprises:
the second pattern transfer layer fully fills the first holes and the first trenches, and further covers the upper surface of the first pattern transfer layer; and
before forming the second mask layer, a part of the second pattern transfer layer located on the upper surface of the first pattern transfer layer is removed to reserve a part of the second pattern transfer layer located in the first holes and in the first trenches.

9. The semiconductor structure manufacturing method of claim 1, wherein forming the third pattern transfer layer further comprises:
the third pattern transfer layer fully fills the second holes and further covers an upper surface of the first pattern transfer layer, an upper surface of the second pattern transfer layer, an upper surface of the first isolation layer and an upper surface of the second isolation layer; and
removing a part of the third pattern transfer layer located on the upper surface of the first pattern transfer layer, on the upper surface of the second pattern transfer layer, on the upper surface of the first isolation layer and on the upper surface of the second isolation layer to at least expose the upper surface of the first isolation layer and the upper surface of the second isolation layer, and reserving a part of the third pattern transfer layer located in the second holes.

10. The semiconductor structure manufacturing method of claim 2, wherein forming the first pattern transfer layer on the conductive layer further comprises:
forming a final pattern transfer layer on the conductive layer, and forming the first pattern transfer layer on the final pattern transfer layer.

11. The semiconductor structure manufacturing method of claim 10, wherein removing the first isolation layer and the second isolation layer by etching to form the isolation trenches comprises: removing the first isolation layer and the second isolation layer by selective etching to form the isolation trenches and reserve the first pattern transfer layer, the second pattern transfer layer and the third pattern transfer layer located between the isolation trenches.

12. The semiconductor structure manufacturing method of claim 11, wherein removing the first pattern transfer layer, the second pattern transfer layer and the third pattern transfer layer on the conductive layer comprises: etching the final pattern transfer layer along the isolation trenches by self-aligned etching, and at the same time, removing the first pattern transfer layer, the second pattern transfer layer and the third pattern transfer layer.

13. The semiconductor structure manufacturing method of claim 12, wherein etching the conductive layer along the isolation trenches comprises: etching the conductive layer by using the etched final pattern transfer layer as a mask.

14. The semiconductor structure manufacturing method of claim 1, wherein the second pattern transfer layer and the third pattern transfer layer are formed by spin-on hardmask.

15. A semiconductor structure manufactured by the method of claim 1, comprising a substrate and contact pad structures formed on the substrate, wherein one end of the contact pad structure is connected to a transistor structure in the substrate, and the other end of the contact pad structure is configured to be connected to the capacitor structure.

16. The semiconductor structure of claim 15, wherein after forming the third pattern transfer layer, the method further comprises:
removing the first isolation layer and the second isolation layer by etching to form isolation trenches, and etching the conductive layer along the isolation trenches; and
removing the first pattern transfer layer, the second pattern transfer layer and the third pattern transfer layer on the conductive layer to form contact pad structures.

17. The semiconductor structure of claim 15, wherein a region, which corresponds to the core region, of the first mask layer is provided with the first hole-shaped patterns, a region, which corresponds to the edge region, of the first mask layer is further provided with a plurality of first trench-shaped patterns, the first trench-shaped pattern extends along a direction away from the core region, and the plurality of first trench-shaped patterns are disposed in parallel and at intervals;
while etching the first pattern transfer layer by using the first mask layer as a mask, first trenches areformed in a region, which corresponds to the edge region, of the first pattern transfer layer;
while forming the first isolation layer, the first isolation layer further at least covers side walls of the first trenches; and
while forming the second pattern transfer layer, the second pattern transfer layer fills the first trenches.

18. The semiconductor structure of claim 17, wherein a width size of the second pattern transfer layer filling the first trenches is the same as a width size of the remaining first pattern transfer layer located in the corresponding edge region after forming the first trenches.

19. The semiconductor structure of claim 17, wherein a region, which corresponds to the core region, of the second mask layer is provided with the second hole-shaped patterns, a region, which corresponds to the edge region, of the second mask layer is provided with a plurality of third hole-shaped patterns, and a projection of the third hole-shaped pattern onto the first pattern transfer layer or the second pattern transfer layer is located between the adjacent first isolation layers covering the side walls of the first trenches; and
while etching the first pattern transfer layer by using the second mask layer as a mask to form the second holes, regions, that respectively correspond to the edge region, of the first pattern transfer layer and the second pattern transfer layer are etched to form third holes corresponding to the third hole-shaped patterns, and side walls of the third holes are in contact with the adjacent first isolation layers; and
while forming the second isolation layer, the second isolation layer further at least fills the third holes.

20. The semiconductor structure of claim 19, wherein the forming the second isolation layer further comprises:
the second isolation layer further covers an upper surface of the first pattern transfer layer or the second pattern transfer layer, and the side walls and bottom walls of the second holes, and the second isolation layer fully fills the third holes,
and wherein before forming the third pattern transfer layer, the method further comprises:
removing a part of the second isolation layer located on the upper surface of the first pattern transfer layer or the second pattern transfer layer, and on the bottom walls of the second holes to reserve a part of the second isolation layer located on the side walls of the second holes and in the third holes.
